(19) United States
(12) Patent Application Publication
(10) Pub. No.: US 2021/0050800 A1
(43) Pub. Date: Feb. 18, 2021

(54) COMPACT ENERGY CONVERSION DEVICE

(71) Applicant: SIERRA NEVADA CORPORATION, Sparks, NV (US)

(72) Inventors: Karl Jones, Parker, CO (US); John Meikle, Melbourne, FL (US); Kevin Neitzel, Parker, CO (US); John Reifenberg, Highlands Ranch, CO (US); Nathan Thomas Eigenfeld, Boulder, CO (US)

(21) Appl. No.: 16/991,867

(22) Filed: Aug. 12, 2020

Related U.S. Application Data
(60) Provisional application No. 62/976,067, filed on Feb. 13, 2020.
(60) Provisional application No. 62/940,123, filed on Nov. 25, 2019.
(60) Provisional application No. 62/885,661, filed on Aug. 12, 2019.

(51) Int. Cl. H02N 1/08

(52) U.S. Cl. CPC H02N 1/08

(57) ABSTRACT

Disclosed are devices, systems, and methods for compact energy conversion. In one aspect, the compact energy conversion device includes a transport medium comprising a nanoparticle suspended in a dielectric. The transport medium has a first side and a second side, with the first side opposing the second side. The nanoparticle comprises a conductive metal. The conductive metal is at least partially covered by a monolayer film. The monolayer film is less conductive than the conductive metal. The compact energy conversion device includes a first surface disposed at the first side of the transport medium, and a second surface disposed at the second side of the transport medium. The first side of the transport medium has a work function lower than the second side.

### CROSS-REFERENCE TO RELATED APPLICATIONS

This application claims priority to U.S. Provisional Application No. 62/885,661, filed on Aug. 12, 2019, and titled “THERMAL AND/OR KINETIC ENERGY CONVERSION TO ELECTRICAL ENERGY DEVICE ARCHITECTURE,” and U.S. Provisional Application No. 62/940,123, filed on Nov. 25, 2019, and titled “THERMAL AND/OR KINETIC ENERGY CONVERSION TO ELECTRICAL ENERGY DEVICE ARCHITECTURE,” and U.S. Provisional Application No. 62/976,067, filed on Feb. 13, 2020, and titled “COMPACT ENERGY CONVERSION DEVICE,” the entirety of each of which is incorporated by reference herein.

### TECHNICAL FIELD

The subject matter described herein relates to energy conversion devices, and, more particularly, kinetic energy conversion to electrical energy (KEC) devices.

### BACKGROUND

Harvesting naturally occurring energy is increasingly important to support global power demands. For example, heat freely available in the environment may be converted to mechanical or electrical energy for powering appliances, vehicles, and buildings. Energy conversion devices may increase their capacity and efficiency by increasing their specific power and power density. Specific power of a device is measured as the power output of the device divided by its mass (e.g., W/kg). Power density of a device is measured as the power output per unit volume (e.g., W/m³). Maximizing the specific power and the power density of a device is critical to powering components and systems that utilize the energy conversion device.

### SUMMARY

Aspects of the current subject matter include various embodiments of a compact energy conversion device. In one aspect, an energy conversion device is described that includes a transport medium comprising a nanoparticle suspended in a dielectric. The transport medium has a first side and a second side, with the first side opposing the second side. The nanoparticle comprises a conductive metal. The conductive metal is at least partially covered by a monolayer film. The monolayer film is less conductive than the conductive metal. The compact energy conversion device includes a first surface disposed at the first side of the transport medium with the first surface having a first work function. The energy conversion device also includes a second surface disposed at the second side of the transport medium with the second surface having a second work function. The first side work function is lower than the second work function.

In some variations, one or more of the features disclosed herein including the following features can optionally be included in any feasible combination. In some implementations, a nanoparticle work function is lower than the second work function. In some variations, the dielectric is a solution comprising at least one of silicone oil, purified water, hexane, toluene, and tetradecane. In some variations, the monolayer film has a thickness less than ten nanometers, and wherein the conductive metal of the nanoparticle comprises at least one of gold, silver, platinum, titanium, platinum, lanthanum hexaboride, and copper. In some variations, the nanoparticle further comprises a core-shell nanoparticle, the core-shell nanoparticle including a conductive core and an insulative film. In some variations, the first surface comprises a surface feature including at least one of a spike, a sphere, a pin, and a pillar. In some variations, the first surface comprises at least one of Cs2O, CsF, CH3OH, CsCO3, chlorine compounds, fluorine compounds, cesium compounds, non-stoichiometric cesium oxides, and cesium fluorides. In some variations, the first surface comprises a semi-conductive material, the semi-conductive material being doped with at least one of aluminum, antimony, bismuth, gold, phosphorous and boron. In some variations, the first surface has covalent bonding in-plane and Van der Waals bonding out of plane, and wherein the first surface comprises at least one of WSe2, MoS2, MoTe2, and h-BN.

In another aspect, an energy conversion device is described that includes a first electrode having a first surface with the first surface having a first work function. The energy conversion device includes a second electrode having a second surface with the second surface having a second work function. The energy conversion device includes a transport medium interposed between the first surface and the second surface, the transport medium comprising traps suspended in a dielectric. The first work function is lower than the second work function.

In some variations, one or more of the features disclosed herein including the following features can optionally be included in any feasible combination. In some implementations, the dielectric comprises a lattice of Ta2O5 and a tantalum dopant and the trap includes an opening in the lattice of Ta2O5 where no atom is bonded to the tantalum dopant. In some implementations, the first electrode and the second electrode have a surface treatment comprising at least one of Cs2O, CsF, CH3OH, CsCO3, chlorine compounds, fluorine compounds, cesium compounds, non-stoichiometric cesium oxides, and cesium fluorides. In some implementations, the dielectric is a polycrystalline layer having a crystalline structure, the traps are nanoparticles including a conductive metal, and wherein the first electrode comprises a semi-conductive material and the second electrode comprises at least one of Ti, Ni, Cu, Pd, Ag, Hf, ITO, W, Ir, Pt, Re, W, Mo and Au.

In yet another aspect, an energy conversion device is described including a first electrode having a first surface and a second surface in which the first surface and the second surface are associated with a first work function. The energy conversion device includes a second electrode facing the first surface with the second electrode associated with a second work function. The energy conversion device includes a third electrode facing the second surface with the third electrode associated with the second work function. The energy conversion device includes a first transport medium interposed between the first electrode and the second electrode. The energy conversion device includes a second transport medium interposed between the first electrode and the third electrode. The second electrode and the third electrode are electrically coupled and the first work function is lower than the second work function.

In some variations, one or more of the features disclosed herein including the following features can optionally be included in any feasible combination. In some implementations, the first electrode and the second electrode are on opposing sides of the first transport medium, and wherein the second electrode and the third electrode are on opposing sides of the second transport medium. In some implementations, the first surface contacts the first transport medium and the second surface contacts the second transport medium. In some implementations, the energy conversion device further includes a first lead, the first lead oriented in a first direction non-parallel to the first surface and the second surface, the first lead electrically connected to the second electrode and the third electrode; and a second lead, the second lead oriented in a second direction non-perpendicular to the first lead, the second lead electrically coupled to the first electrode. In some implementations, the first direction is the same as the second direction, and wherein the first lead extends at least a distance between the second electrode and the third electrode. In some implementations, the second lead faces an exposed region of the first electrode, and wherein the first lead is on an opposing side of the exposed region of the first electrode.

The details of one or more variations of the subject matter described herein are set forth in the accompanying drawings and the description below. Other features and advantages of the subject matter described herein will be apparent from the description and drawings, and from the claims. While certain features of the currently disclosed subject matter are described for illustrative purposes in relation to proactive database scaling, it should be readily understood that such features are not intended to be limiting. The claims that follow this disclosure are intended to define the scope of the protected subject matter.

### DESCRIPTION OF DRAWINGS

The accompanying drawings are intended to be illustrative and may not necessarily be to scale in absolute terms or comparatively. Also, the relative placement of features and elements may be modified for the purpose of illustrative clarity. The accompanying drawings, which are incorporated in and constitute a part of this specification, show certain aspects of the subject matter disclosed herein and, together with the description, help explain some of the principles associated with the disclosed implementations. In the drawings,

FIG. 1A shows a schematic representation of an architecture for an energy conversion device, in accordance with some example embodiments;

FIG. 1B shows an energy-generating layer including a surface treatment, in accordance with some example embodiments;

FIG. 1C shows another energy-generating layer including a low work function surface and a high work function surface, in accordance with some example embodiments;

FIG. 2A shows another energy-generating layer including a nanoparticle solution, in accordance with some example embodiments;

FIG. 2B shows a schematic representation of an architecture of an energy conversion device including the nanoparticle solution, in accordance with some example embodiments;

FIG. 3A shows nanoparticles in accordance with some example embodiments;

FIG. 3B shows nanoparticles in a transport medium interposed between the emitter and the collector in accordance with some example embodiments;

FIG. 4 shows an atomic layer including a trap for trap-assisted charge carrier transport, in accordance with some example embodiments;

FIG. 5 shows a polyatomic layer including a trap for trap-assisted charge carrier transport, in accordance with some example embodiments;

FIG. 6 shows a bandgap diagram depicting applied charge carrier tunneling techniques and Poole-Frenkel Emission in accordance with some example embodiments;

FIG. 7 shows another bandgap diagram depicting applied charge carrier tunneling techniques and Poole-Frenkel Emission in accordance with some example embodiments;

FIG. 8A shows an exploded view of standoff pillars resulting from an etch, in accordance with some example embodiments;

FIG. 8B shows a cross-sectional view of standoff pillars resulting from an etch, in accordance with some example embodiments;

FIG. 8C shows a side view of standoff pillars resulting from an etch, in accordance with some example embodiments;

FIG. 8D shows a top view of standoff pillars resulting from an etch, in accordance with some example embodiments;

FIG. 9A shows an exploded view of standoff columns resulting from an etch, in accordance with some example embodiments;

FIG. 9B shows a cross-sectional view of standoff columns resulting from an etch, in accordance with some example embodiments;

FIG. 9C shows a side view of standoff columns resulting from an etch, in accordance with some example embodiments; and

FIG. 9D shows a top view of standoff columns resulting from an etch, in accordance with some example embodiments.

When practical, similar reference numbers denote similar structures, features, or elements.

### DETAILED DESCRIPTION

Harvesting naturally occurring energy is increasingly important to support global power demands. For example, kinetic energy can be converted to electrical energy via the use of material properties and quantum physics. The converted electrical energy may be used for powering appliances, vehicles, and buildings. Energy conversion devices may increase their appeal and utilization by increasing their specific power and power density. Specific power of a device is measured as the power output of the device divided by its mass (e.g., W/kg). Power density of a device is measured as the power output per unit volume (e.g., W/m³). Maximizing the specific power and the power density of a device is critical to powering components and systems that utilize the energy conversion device.

The specific power and power density of a device may be maximized through improved energy conversion physics. For example, varying the thickness of the insulating material positioned between an emitter and a collector varies the specific power and power density of the device. But the specific power and power density may also be improved by increasing the compactness of the energy conversion device. For example, increasing the number of emitter and collector electrodes within a fixed space increases the specific power and power density of the energy conversion device. The specific power and power density directly describe the mass and volume efficiency of the energy conversion device. The mass and volume efficiency are critical parameters at the system and vehicle design level for a vehicle or other components that utilize such a device.

As the metrics suggest, each of the metrics may be improved in at least two manners: power production improvement (e.g., kinetic energy to electrical energy conversion) or compactness (mass or volume) of the device. To date, a majority of technology development of such devices has focused on power production improvement while the compactness of the architecture of the devices has remained relatively unchanged. Specifically, the conventional device architecture consists of a single cell that includes an emitter, a transport medium (which may take many forms but is usually in the form of a vacuum), and a collector. The single cell is repeated to scale the output for larger magnitude applications. This repeating architecture is inefficient from a compactness standpoint and may limit the scalability of the conversion device.

Disclosed herein are improved architectural approaches and compositions of matter for an energy conversion device. The architectural approaches improve upon the compactness of the architecture by using a stacked architecture for the device. The compositions of matter improve the power conversion of the device by taking advantage of charge carrier interaction. The device architecture disclosed herein may be configured pursuant to at least three features: (1) a multilayered monolithic architecture that allows both sides of the electrodes to be used for emission/collection, having thermal/electrical interfaces positioned on side(s) of the device instead of the top/bottom as in conventional devices; (2) compositions of matter facilitating charge carrier interaction for improved power conversion; and (3) methods that enable the use of thinner components in the device. Such features provide significant improvement to specific power and power density for energy conversion devices. The aforementioned approach leads to improved specific power and power density that make viable new applications for energy conversion technology.

The energy conversion device may be configured according to a stacked architecture. The stacked architecture may include alternating layers of electrodes and transport medium material. More specifically, the stacked architecture includes emitter electrodes and collector electrodes with the collector electrodes separating each set of the emitter electrodes. The transport medium may separate each emitter electrode and collector electrode.

The energy conversion device may comprise a substrate. The substrate may be provided as a base for the stacked architecture. The substrate may include multiple layers bonded together. Layers in the substrate may include a thermal insulation layer, a sealant layer, a bonding layer, a structural layer, and an insulative layer. The substrate may be treated with a surface treatment to prevent energy loss. Optionally, the substrate may include a layer of semiconductor material upon which the stacked architecture is developed. In a non-limiting example implementation, the substrate may comprise polyimide, a polymethyldisiloxane, a polystyrene, an epoxy, a polypropylene, a poly(methylmethacrylate), a polyethylene, and a poly(vinyl chloride). In some embodiments, a layer comprising the substrate may include a continuous covering of atoms or nanoparticles across a surface. Alternatively, and/or additionally, the layer comprising the substrate may include atoms or nanoparticles dispersed across the surface with portions of the surface exposed.

In a non-limiting example implementation, the stacked architecture at least partially includes alternating emitter and collector electrodes, each having opposing sides and an isolated transport medium between each electrode. The stacking architecture enables both sides of each electrode to be used for emission/collection in the energy conversion process. In addition, the device includes thermal/electrical interfaces that are positioned on opposed sides of the device to thereby provide all of the electrodes with access to the thermal/electrical interfaces.

The device may be manufactured pursuant to nanoscale manufacturing processes. Additionally, the electrodes and any other necessary structural components may be manufactured pursuant to nanoscale manufacturing to make them much thinner than conventional energy conversion device manufacturing. Moreover, nanoscale manufacturing confers other benefits such as precise geometry definitions, more controlled chemistry, controlled roughness, tighter tolerances, and process repeatability.

The term “emitter electrode” is not limited to the definition of an electrode from which charge carriers are emitted to the transport medium. The term “emitter electrode” may also include an electrode from which more charge carriers are emitted to the transport medium relative to another electrode (e.g., the collector electrode) as some charge carriers may be generated from by transport medium. Similarly, the term “collector electrode” is not strictly limited to an electrode from which charge carriers are collected from the transport medium. The term “collector electrode” may also include an electrode from which more charge carriers are collected from the transport medium relative to another electrode (e.g., the emitter electrode) as some charge carriers may be generated by the transport medium.

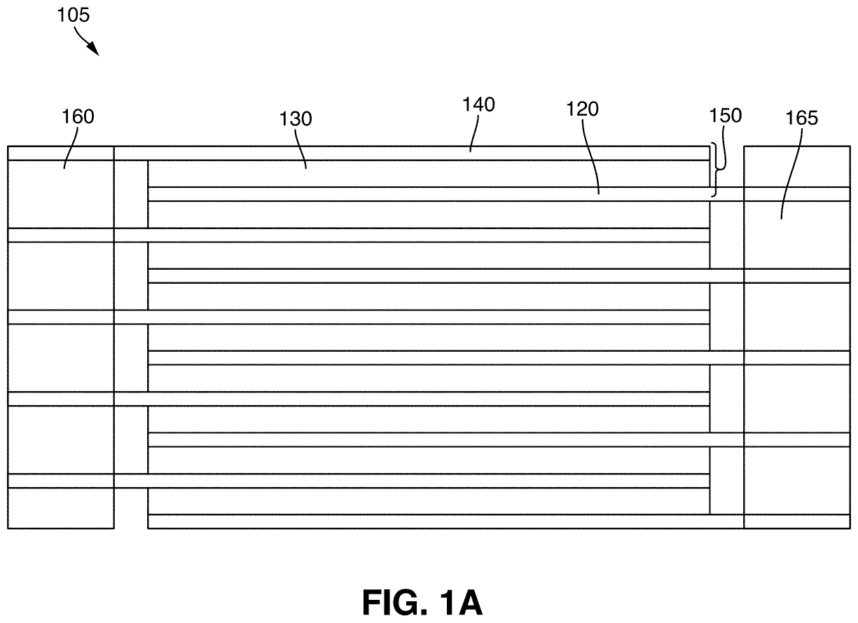

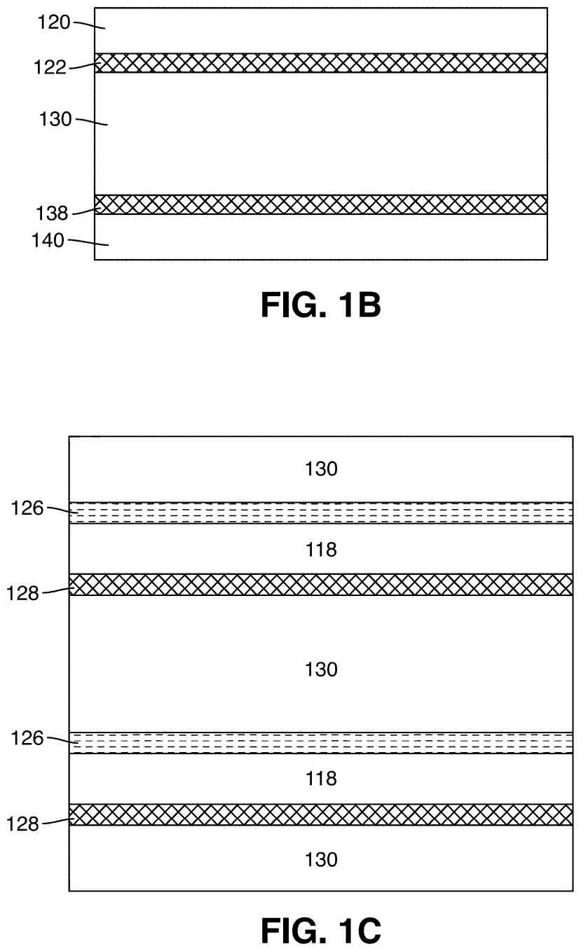

FIG. 1A shows a schematic representation of an architecture for an energy conversion device 105. The energy conversion device 105 includes at least a series of alternating electrodes separated by a transport medium 130. The series of alternating electrodes separated by a transport medium 130 may be organized into power-generating cells. The energy conversion device 105 includes at least one cell 150. Each cell 150 includes at least two electrodes and a transport medium 130. The two electrodes may comprise an emitter electrode 120 and a collector electrode 140. The emitter electrode 120 and the collector electrode 140 may be elongated and non-orthogonal to one other. The transport medium 130 may be interposed between the at least two elongated electrodes such that the two elongated electrodes do not come into direct contact with each other between the two ends of the transport medium 130.

The cell 150 harvests kinetic energy to produce electric energy. For example, a difference in work function between the two electrodes results in a charge carrier transport between the emitter electrode 120 and the collector electrode 140. Higher temperatures may increase the rate of energy conversion to electrical energy. For instance, a high emitter electrode temperature raises electron energy, enabling more charge carriers to transport across the transport medium 130. In some embodiments, the output of the energy conversion device 105 is a large voltage difference between the emitter electrode 120 and the collector electrode 140 that is capable of producing a current ranging from picoAmps to milliAmps per square centimeter. In some embodiments, the output of the energy conversion device 105 is a current flowing from the emitter electrode 120 to the collector electrode 140 with a modest voltage difference. In some embodiments, the output of the energy conversion device 105 is a current flowing from the collector electrode 140 to the emitter electrode 120.

The cell 150 may be stacked sequentially to create a pattern of cells across the energy conversion device 105. The pattern of cells may include some collector electrodes structurally integrated into two cells. For example, a collector electrode 140 may be a collector electrode for two or more adjacent power-generating cells. More specifically, the collector electrode 140 may share a surface with each of the adjacent power-generating cells. This results in the collector electrode 140 being shared between at least two cells. Additionally, the collector electrode 140 may have opposing planar sides where each planar side interfaces with a different power-generating cell. In this manner, the stacked architecture enables both sides of the electrodes to be used for emission/collection, which yields increased compactness.

The electrodes may be positioned in a juxtaposed, stacked configuration. The electrodes may include a plurality of collector electrodes that are juxtaposed with a corresponding plurality of emitter electrodes and positioned in a stacked relationship. The electrodes may be separated from one another via a transport medium 130, the transport medium 130 potentially comprising a variety of materials or a vacuum. Each transport medium 130 may be sandwiched between an emitter electrode 120 and a collector electrode 140. The stack thus forms a vertical series of cells in which at least one collector electrode 140 is stacked atop a corresponding emitter electrode 120 with a transport medium 130 therebetween. In some embodiments, each cell 150 may have the same dimensions (e.g., length and width) as the other cells in the energy conversion device 105. The pattern of cells may extend in a vertical direction or a horizontal direction.

Electrodes from each cell 150 may be electrically connected to the corresponding electrodes in an adjacent cell with a conducting material, such as a wire, a via hole, a solder, and/or a surface contact. For example, an emitter electrode 120 from a first cell is electrically connected with another emitter electrode of an adjacent cell through a surface contact. In another example, the collector electrode 140 from a first cell is electrically connected with another collector electrode of the adjacent cell through a wire. The electrodes of the cells may be interconnected by wiring, via holes, soldering, and/or surface contacts.

Thus, the cell 150 may be formed by (1) a collector electrode 140 having a top surface and a bottom surface; (2) an emitter electrode 120 having a top surface and a bottom surface; and (3) a transport medium 130 separating or otherwise interposed between the collector electrode 140 and the emitter electrode 120. The architecture may include a series of vertically arranged energy conversion cells. Alternatively, and/or additionally, the architecture may include a series of horizontally arranged energy conversion cells.

The cells may be stacked in any direction and to any dimension to scale output power. For example, additional cells may be stacked to scale output power. The thickness of the stacked architecture may be proportional to the power output. The cells may be co-power generating layers that are electrically interconnected or otherwise coupled in any of a wide variety of combination of series or parallel connections to achieve a desired power output.

The energy conversion device 105 may include a pair of opposed, transverse side regions with a corresponding lead positioned on each side region (a collector lead on one side region and an emitter lead on an opposite side region). The layout of the side regions and the corresponding leads may facilitate the interconnection of the electrodes of the energy conversion device 105. For example, the leads may face the exposed sides of the electrodes to make a connection to the corresponding electrodes. In some embodiments, the energy conversion cells are stacked in a vertical orientation, or in a direction non-orthogonal to the electrode surfaces, each cell 150 including at least one collector electrode 140 stacked atop a corresponding emitter electrode 120 with the transport medium 130 positioned therebetween. With this layout, each of the electrodes is exposed at the sides and may be electrically coupled to the leads on each side region. In this regard, at least one collector lead 160 is positioned on a first side region of the device such that at least one collector lead 160 is coupled to a corresponding combination of collector electrode 140. In this manner, each of the collector electrodes is directly coupled or otherwise exposed to a corresponding collector lead 160.

In addition, at least one emitter lead 165 is positioned on a second, opposite side region of the energy conversion device 105. Thus, at least one emitter lead 165 is directly coupled or otherwise exposed to a combination of emitter electrode 120 and transport medium 130.

An emitter lead 165 and a collector lead 160 electrically connect to the emitter electrode 120 and the collector electrode 140, respectively. The emitter lead 165 and the collector lead 160 may be connected to at least one electrically driven component. The emitter lead 165 and the collector lead 160 may also be connected to any number of other devices in any number of series or parallel configurations. The leads may be scaled to maximize power output and efficiency. The leads may be made out of any conductive material.

Each collector electrode 140 and emitter electrode 120 may extend laterally a planar element (such as a wafer) having a thickness as well as a top side and a bottom side. Each electrode may be formed of one or more layers of material. For example, two or more metals may be layered to form the collector electrode 140. In another example, the emitter electrode 120 may be multilayers of thin films. The configuration of the electrodes, as well as the relative positioning of the electrodes, may vary. For example, the electrodes do not necessarily have to be positioned in a stacked, vertical orientation. The electrodes may also have shapes other than a wafer. In an example implementation, the electrodes are positioned to extend radially outward, such as from a core or a center point. The collector electrodes, emitter electrodes, and transport medium 130 may also be positioned in a concentric arrangement. In some embodiments, the layers comprising the electrode may include a continuous covering of atoms or nanoparticles across a surface. Alternatively, and/or additionally, the layers comprising the electrode may include atoms or nanoparticles dispersed across the surface with portions of the surface exposed.

Each emitter electrode 120 and/or collector electrode 140 may comprise a conductive material. In some embodiments, the emitter electrode 120 and/or the collector electrode 140 may comprise an alkali metal such as Li, K, Na, Rb, Cs, and/or the like. In some embodiments, the emitter electrode 120 and/or the collector electrode 140 comprise an alkali earth metal, such as Be, Mg, Ca, Sr, Ba, and/or the like. In some embodiments, the emitter electrode 120 and/or the collector electrode 140 comprise a transition metal, such as Ti, Ni, Cu, Pd, Ag, Hf, W, Ir, Pt, Re, W, Mo, Au, and/or the like. In some embodiments, the emitter electrode 120 and/or the collector electrode 140 comprise a post-transition metal, such as Al, Ga, In, Tl, Sn, Pb, and/or the like. In some embodiments, the emitter electrode 120 and/or the collector electrode 140 comprise a metalloid, such as B, Si, Ge, As, Te, and/or the like. In at least one non-limiting implementation, the surface of the emitter electrode 120 comprises Ti, Ni, Cu, Pd, Ag, Hf, W, Ir, or Au, and the surface of the collector electrode 140 comprises Re, Pt, W, or Mo. In another non-limiting implementation, the surface of the collector electrode 140 comprises Ti, Ni, Cu, Pd, Ag, Hf, W, Ir, or Au, and the surface of the emitter electrode 120 comprises Re, Pt, W, or Mo.

The emitter electrode 120 and the collector electrode 140 may comprise the same conducting material. The emitter electrode 120 and the collector electrode 140 comprising the same conducting material may have different work functions. For example, the emitter electrode 120 may have a surface treatment resulting in a lower work function than the work function of the collector electrode 140. Similarly, the collector electrode 140 may have a surface treatment creating a higher work function in the collector electrode 140 than the work function of the emitter electrode 120.

In some embodiments, the emitter electrode 120 and the collector electrode 140 are made of different conducting materials. For example, the emitter electrode 120 may comprise aluminum and the collector electrode 140 may comprise platinum. The conducting materials may be selected to achieve a desired work function and energy barrier behavior. For example, the emitter electrode 120 may comprise a conducting material having a work function less than the work function of the collector electrode material. The emitter electrode 120 may have a lower work function and the collector electrode 140 may have a higher work function. The charge carrier flow within the externally connected circuit is driven by this difference in work function between the emitter electrode 120 and the collector electrode 140, resulting in charge carrier flow between the emitter electrode 120 and the collector electrode 140. In some non-limiting implementations, the charge carriers may flow through the transport medium 130 from the higher work function to the lower work function. Charge carriers may flow when the device is in a non-equilibrium state. The non-equilibrium state may be attained by a different work functions at the emitter electrode 120 and the collector electrode 140. The non-equilibrium state may also be attained by a discontinuous energy band within the transport layer. In some embodiments, the transport layer maintains its insulative properties while allowing leakage of charge carriers between the electrodes. In some embodiments, the transport layer is semi-conducting with a sufficient bandgap to prevent electrical shorting between the electrodes. In some embodiments, the non-equilibrium state may be induced by changing the features such as an energy barrier height relative to the fermi level, an energy barrier height relative to vacuum, an energy barrier slope, a density of traps within the energy barrier, a depth of the traps within the energy barrier, and an intermediate stage adjacent to the energy barrier. In some embodiments, the non-equilibrium state may be induced by unique interaction between the charge carriers and other energy modes, such as, but not limited to, phonons. In some embodiments, interactions associated with polarons or excitons may induce a non-equilibrium state. In some embodiments, differing dominant tunneling behavior such as through barrier tunneling or over barrier tunneling between the surface of the emitter electrode 120 and the surface of the collector electrode 140 may induce a non-equilibrium state.

The emitter electrode 120 and/or the collector electrode 140 may comprise a semi-conductive material. The semi-conductive material may be undoped or doped. The dopant applied to the semi-conductive material may be slightly more conductive than the semi-conductive material of the emitter electrode 120 and the collector electrode 140. In some embodiments, the dopant may be dispersed from the top surface of the electrode to the bottom surface of the electrode. Alternatively, and/or additionally, the dopant may be concentrated at regions near the surfaces of the collector electrode 140 or the emitter electrode 120. The semi-conductive material may be Si-based or Ga-based with aluminum, antimony, bismuth, gold, phosphorous, boron, and/or the like as potential dopant options.

The emitter electrode 120 and/or the collector electrode 140 may comprise a 2D material. The 2D material may include crystalline material with a single uniform layer of atoms or molecules. For example, the 2D material may be a uniform layer of graphene, Si2BN, borophene, black phosphorus, tungsten disulfide, and/or the like. The 2D material may be attached to a structural support. For example, the structural support may extend laterally alongside the emitter and/or the collector electrode to prevent atomic diffusion and migration. The thickness of the 2D material may be as thin as a single angstrom thick. The 2D material may be placed within the plane and extend outside of the plane. The 2D material may behave as a coating. In some embodiments, the 2D material may be coupled to a conductive material of the electrode. In some embodiments, the 2D material may include a continuous covering of atoms or nanoparticles across a surface. Alternatively, and/or additionally, the 2D material may include atoms or nanoparticles dispersed across the surface with portions of the surface exposed.

The emitter electrode 120 and/or the collector electrode 140 may comprise a heterostructural material. The heterostructural material (Van der Waals heterostructures) may layer 2D materials with the distinguishing feature of having covalent bonding in-plane and Van der Waals force/bonding out of plane, creating isotropic material properties. The heterostructural material may comprise a compound, such as WSe2, MoS2, MoTe2, h-BN, Re, Pt, W, Mo, and/or the like. In some embodiments, the emitter electrode 120 comprises WSe2, MoS2, MoTe2, or h-BN and the collector electrode 140 comprises oxidized or nonoxidized Re, Pt, W, or Mo. In some embodiments, the collector electrode 140 comprises WSe2, MoS2, MoTe2, or h-BN and the emitter electrode 120 comprises oxidized or nonoxidized Re, Pt, W, or Mo. In some embodiments, the layers of the heterostructural material may include a continuous covering of atoms or nanoparticles across a surface. Alternatively, and/or additionally, the layers of the heterostructural material may include atoms or nanoparticles dispersed across the surface with portions of the surface exposed.

Alternatively, and/or additionally, the emitter electrode 120 and the collector electrode 140 may comprise any other suitable conducting material or combination, such as a metal alloy, a compound, and/or a mixture. For example, the emitter electrode 120 may comprise Indium Tin Oxide. Furthermore, the emitter electrode 120 and the collector electrode 140 may constitute different materials and may have different structures. For example, the emitter electrode 120 may be a semiconductor and the collector electrode 140 may be a metal. In another example, the emitter electrode 120 may be a 2D material and the collector electrode 140 may be a heterostructural material.

The thickness of the emitter electrode 120 and collector electrode 140 may measure between 0.1 nm and 100 μm in diameter. In some embodiments, the thickness of the emitter and the collector electrode is at or about 10 nm for density critical applications. The thickness of the electrodes may be reduced to increase the packaging density. In some embodiments, the collector electrode 140 may have a thickness greater than the emitter electrode 120. In some embodiments, the emitter electrode 120 may have a thickness greater than the collector electrode 140. In some embodiments, the emitter electrode 120 and/or the collector electrode 140 provide structural support for the stacked architecture. The emitter and collector electrodes may be fabricated using deposition techniques, such as PVD, CVD, spin-on coating, self-assembly, etching, lithography, and/or a similar manufacturing process.

FIG. 1B shows an energy-generating layer including an optional surface treatment, in accordance with some example embodiments. The work function of the surface of the emitter electrode and the collector electrode may be modified through a surface treatment. An emitter surface treatment 122 may be added to a surface of the emitter electrode 120 to modify the work function of the emitter electrode 120. The collector electrode 140 may also include a collector surface treatment 138 configured to modify its work function, resulting in a desired work function differential between an emitter electrode 120 and a collector electrode 140.

The emitter surface treatment 122 and the collector surface treatment 138 may include surface features such as roughness, spikes, spheres, pins, pits, pillars, and/or the like. The surface features may be spaced from each other to adjust the work function of the emitter electrode 120 and the collector electrode 140. More surface features may be added to the surface of the emitter electrode 120 and/or the collector electrode 140 until the desired work function differential is achieved. The surface features may be created through deposition techniques, such as PVD, CVD, spin-on coating, self-assembly, etching, lithography, and/or a similar manufacturing process. The surface features may control the sensitivity of tunneling of charge carriers between the emitter electrode 120 and the collector electrode 140.

The emitter surface treatment 122 and/or the collector surface treatment 138 may include a chemical application. The chemical application may lower the work function until the desired work function differential is achieved between the emitter electrode 120 and the collector electrode 140. For example, the emitter surface treatment 122 may be treated with Cs2O to lower its work function. The chemical may comprise Cs2O, CsF, CH3OH, CsCO3, chlorine compounds, fluorine compounds, cesium compounds, non-stoichiometric cesium oxides, and/or cesium fluorides. The collector surface treatment 138 may aim to increase the work function, and include chemicals such as NO2-PyT (PyT standing for pyrene-tetraone), Br-PyT, Cl-ITO, Re, Pt, W, Mo and/or the like. In some embodiments, the collector surface treatment 138 may comprise NO2-PyT (PyT standing for pyrene-tetraone), Br-PyT, Cl-ITO, Re, Pt, W, Mo and/or the like

The chemical application may include a uniform layer of atoms or compounds along the length of the emitter electrode 120 and/or the collector electrode 140. In some embodiments, the chemical treatment may include a continuous covering of atoms or nanoparticles across a surface. Alternatively, and/or additionally, the chemical treatment may include atoms or nanoparticles dispersed across the surface with portions of the surface exposed. In some embodiments, the emitter surface treatment 122 and/or the collector surface treatment 138 may be modified with a continuous or non-continuous film containing an impurity that reacts with the electrode. In a non-limiting implementation, the impurity may include Cs2O, CsF, CH3OH, CsCO3, chlorine compounds, fluorine compounds, cesium compounds, non-stoichiometric cesium oxides, and/or cesium fluorides.

The dopant may react with the metal of the electrode to vary the electrical properties (e.g., capacitance, the inductance, the resistance, and the conductivity) of the conductive metal. The dopants may vary in carrier concentration and mobility between the emitter electrode 120 and the collector electrode 140. For example, the dopant may have a greater carrier concentration at the emitter electrode 120 in comparison to the collector electrode 140. In at least one embodiment, the collector surface treatment 138 includes a chemical treatment disposed uniformly along the outside surface along at least one length of the collector electrode 140. Alternatively, and/or additionally, the chemical treatment may be evenly spread across the surface of the collector and/or emitter electrode but only covers a fraction of the total surface area.

Alternatively, and/or additionally, the chemical treatment may be applied in an alternating pattern along the surface of the collector electrode 140 and/or the emitter electrode 120. The thickness of the application of the chemical treatment varies between 0.1 nanometers to 100 nanometers. The emitter surface treatment 122 may be applied to one or both sides of the emitter electrode 120. The collector surface treatment 138 may be applied to one or both sides of the collector electrode 140. The chemical treatment may be applied using deposition techniques, such as PVD, CVD, spin-on coating, self-assembly, etching, lithography, and/or a similar manufacturing process.

The emitter surface treatment 122 and/or the collector surface treatment 138 may include a modified layer. The modified layer may include a layer of Cs, Fr, K, Cl, F, and/or the like. In some embodiments, the modified layer may include a continuous covering of atoms or nanoparticles across a surface. Alternatively, and/or additionally, the modified layer may include atoms or nanoparticles dispersed across the surface with portions of the surface exposed.

In some embodiment, the emitter surface treatment 122 and the collector surface treatment 138 have a larger planar dimension than the transport medium 130 in at least one direction to achieve electrical interconnection with the emitter lead 165 or the collector lead 160. In some embodiments, the emitter surface treatment 122 and/or the collector surface treatment 138 extend up to or beyond the planar dimension of the transport medium 130. In some embodiments, the transport medium 130 material and the adjacent emitter surface treatment 122 or adjacent collector surface treatment 138 are flush along a vertical side of the energy conversion device 105. In some implementations, the emitter electrode 120 and the collector electrode 140 have a larger planar dimension than the transport medium 130 in at least one direction to achieve electrical interconnection with the emitter lead 165 or the collector lead 160. In some embodiments, the emitter electrodes and the collector electrodes extend up to or beyond the planar dimension of the transport medium 130. In some embodiments, the transport medium 130 material and the adjacent collector electrode 140 or emitter electrode 120 are flush along a vertical side of the energy conversion device 105.

Turning again to FIG. 1A, charge carriers may flow between the emitter electrode 120 and the collector electrode 140. The difference in the work function of the emitter electrode 120 and the work function of the collector electrode 140 may result in a charge carrier flow between the two electrodes. In some embodiments, the emitter electrode 120 has a lower work function and the collector electrode 140 has a higher work function. An energy barrier configuration between the two electrodes may reduce the flow of charge carriers between the collector electrode 140 and the emitter electrode 120. In some non-limiting implementations, the energy barrier configuration between the two electrodes may reduce charge carrier transport from the collector electrode 140 to the emitter electrode 120. The transport medium 130 may electrically isolate the emitter electrode 120 and the collector electrode 140 from each other while allowing for charge carrier transport therebetween.

With respect to the transport medium 130, the size and configuration of the transport medium 130 may vary. The transport medium 130 may comprise a vacuum having a thickness of about 0.1 nm to 10.0 μm. The transport medium 130 may also include a gas or a vapor with a corresponding thickness of about 0.1 nm to 10.0 μm where the vapor comprises, for example Cs, metal ions, SF6, C4F8, Ar, and/or the like. The thickness of the transport medium 130 may be 200 nm or less. In one non-limiting implementation, the thickness of the transport medium 130 may be between 1 nm to 10 μm. The transport medium 130 may be interposed between the at least two elongated electrodes such that the two elongated electrodes do not come into direct contact with each other.

The transport medium 130 may also include a solid material including for example: a dielectric insulator such as Al2O3, HfO2, Ta2O5, Nb2O5, SiO2; a 2D material, such as graphene, Si2BN, borophene; a heterostructure materials such as WSe2, MoS2, MoTe2, h-BN, Re, Pt, W, Mo; a semiconductor such as doped/undoped, Si-based, Ga-based material; and/or an organic compound such as one or more polymers, self-assembled monolayers, and/or alkanethiols. The transport medium 130 may be fabricated using deposition techniques, such as PVD, CVD, spin-on coating, self-assembly, etching, lithography, and/or a similar manufacturing process. The transport medium 130 may be a crystalline, amorphous, or polycrystalline based on the deposition technique. In some embodiments, the transport medium 130 may comprise a self-assembled monolayer. In some implementations, the transport medium 130 may comprise various combinations of metals and insulators layered together. For example, the transport medium 130 may include a metal-insulator-metal layer that may be combined with other layers. In another example, the transport medium 130 may include a metal-insulator-metal-insulator-metal that may be combined with other layers. In another example, the transport medium 130 may include a metal-insulator-insulator-metal layer that may be combined with other layers. In some embodiments, the layers of the transport medium 130 may include a continuous covering of atoms or nanoparticles across a surface. Alternatively, and/or additionally, the layer of the transport medium 130 may include atoms or nanoparticles dispersed across the surface with portions of the surface exposed.

Quantum tunneling, such as direct tunneling, Fowler-Nordheim tunneling, trap-assisted tunneling, Poole-Frenkel emission, Schottky effect, and/or thermionic emission may transport charge carriers across the transport medium 130. Transportation of charge carriers across the transport medium may be accomplished by manipulating the characteristics of the energy barrier(s) to achieve a non-equilibrium state. The non-equilibrium state may be achieved by adjusting the work functions of the electrodes and the various features of the energy barrier, such as an energy barrier height relative to the fermi level, an energy barrier height relative to vacuum, an energy barrier slope, a density of traps within the energy barrier, a depth of the traps within the energy barrier, and an intermediate stage adjacent to the energy barrier.

In some embodiments, the disclosed architecture allows for a compact structure and improves efficiency that draws heat from the sides of the device to be absorbed by the emitter and collector leads. The emitter and collector leads, in turn evenly disperse the heat to each of the electrode layers. The device may also include one or more structural features, such as pillars, that enhance or otherwise modify the structural integrity and electrical interconnectivity of the device.

Additional insulating material may be added to maximize the energy conversion efficiency of the device. To maximize efficiency, the emitter electrode 120 may be insulated from colder external elements and the collector electrode 140 may be insulated from warmer external elements. Further, the emitter electrode 120 may be isolated from components electrically connected to the collector electrode 140. Additionally, the collector electrode 140 may be electrically isolated from components electrically connected to the emitter electrode 120. To solve this problem, an insulating wall may cover the stacked cell architecture.

To further maximize energy conversion efficiency, the energy conversion device 105 may include a plurality of conductive leads surrounding the energy conversion device 105 to avoid a temperature gradient across the electrodes. For example, two leads may be placed at opposing ends of the emitter electrodes in one direction and two additional leads may be placed at opposing ends of the collector electrodes in a different direction. The two sets of opposing leads may be sources of thermal energy for the respective electrodes. In this manner, the emitter electrodes and the collector electrodes maintain a consistent temperature gradient from end to end.

The energy conversion device 105 may be encased in a common outer shell to provide an embeddable integrated electrical package. The device may be encased in a common outer shell with an electrically driven component in a common outer shell to provide the embeddable integrated electrical package. Additionally, the energy conversion device 105 may be stacked using semiconductor, CMOS techniques, and/or MEMS packaging techniques including wafer bonding, interposers, wafer thinning, and other processes. These packaging techniques may enhance performance and reduced manufacturing costs.

The thickness of the stacked architecture may be determined by the number of cells or electrical power generating layers. The stacked architecture may be scaled up or down depending on the power demands of the electrically driven component. The stacked architecture may be scaled up or down for a variety of applications.

An external thermal bias may enhance the conversion efficiency from thermal energy to electricity. For example, the device may harvest energy from an engine or human skin to generate electricity. Additionally, an external thermal bias may enhance the conversion efficiency from thermal energy to electricity with increased absolute temperature. The packaging may be designed to conduct thermal energy through electrodes, wires, fins, and/or the like. The packaging may be configured to be attached to buildings, structures, and/or vehicles to capture thermal energy. The packaging may be scaled up or down for a variety of applications.

The energy conversion device 105 may require an external potential difference bias to activate the energy conversion device 105. For example, the current flow may be minimal between the emitter electrode 120 and the collector electrode 140. An external potential difference bias may initiate the current flow. The external voltage bias may be applied between the emitter electrode 120 and the collector electrode 140. Alternatively, and/or additionally, the external voltage bias may be applied between the emitter lead 165 and the collector lead 160.

In use, the emitter electrodes may be exposed to heat to promote charge carrier transport. In some embodiments, the collector electrodes may receive the transferred charge carriers from the emitter electrodes. As mentioned, the gap between the electrodes may be a vacuum but may also be filled with a solid, liquid, or gas. The kinetic energy may be supplied by any of a variety of sources, including but not limited to thermal, chemical, solar, vibrational, or nuclear sources. Thus, energy conversion device 105 may be used to power any of a variety of devices, including but not limited to, waste heat recovery, energy scavenging, co-power generation, and direct energy sources.

The energy conversion device 105 may be activated when connected to an electrical load. An electrically driven component may be provided with a conductive interface (e.g., pads, leads, wires). The electrically driven component may be powered when connected to the energy conversion device 105.

The energy conversion device 105 may be configured to convert energy for stationary power, electric vehicles, urban air mobility, and devices of the IoT. The energy conversion device 105 may be attached to a building structure or a vehicle structure to harvest energy.

FIG. 1C shows another energy-generating layer including a low work function surface and a high work function surface, in accordance with some example embodiments. An electrode 118 may include at least two opposing surfaces. The two opposing surfaces may be approximately parallel to one another. The first opposing surface may contact a low work function surface 126. The second surface may contact a high work function surface 128. Alternatively, the first opposing surface may contact a high work function surface 128 and the second surface may contact a low work function surface 126. In some embodiments, the first opposing surface contacts the transport medium 130 while the second opposing surface of the same electrode contacts a high/low work function surface. In some embodiments, the second opposing surface contacts the transport medium 130 while the first opposing surface of the same electrode contacts a high work function surface 128 or a low work function surface 126.

The high work function surface 128 and the low work function surface 126 may be a material disposed on the electrode 118. For instance, the high work function surface 128 and the low work function surface 126 may comprise the same material. The difference in work function between the high work function surface 128 and the low work function surface 126 may be achieved by varying the thickness of the material. For example, the high work function surface 128 may be thinner than the low work function surface 126. In some embodiments, the high work function surface 128 and the low work function surface 126 may comprise different materials. For example, the high work function surface 128 may be an aluminum layer disposed on the upper side of the electrode 118 and the low work function surface 126 may be a platinum layer disposed on the lower side of the electrode 118. The materials may be selected to achieve a desired work function and energy barrier behavior.

The high work function surface 128 and/or the low work function surface 126 may comprise a semi-conductive material. The semi-conductive material may be undoped or doped. The dopant may be slightly more conductive than the semi-conductive material of the emitter electrode 120 and the collector electrode 140. Alternatively, and/or additionally, the semi-conductive material may be applied in an alternating pattern across the collector electrode 140 or the emitter electrode 120. The semi-conductive material may be Si-based or Ga-based with aluminum, antimony, bismuth, gold, phosphorous, boron, and/or as potential dopant options.

The high work function surface 128 and/or the low work function surface 126 may comprise a 2D material. The 2D material may include a crystalline material including a single uniform layer of atoms or molecules. For example, the 2D material may be a uniform layer of graphene, Si2BN, borophene, and/or the like. The high work function surface 128 and/or the low work function surface 126 may comprise a heterostructural material. The heterostructural material may comprise a compound, such as WSe2, MoS2, MoTe2, h-BN, Re, Pt, W, Mo, and/or the like. In some embodiments, the high work function surface 128 comprises WSe2, MoS2, MoTe2, or h-BN and the low work function surface 126 comprises oxidized or nonoxidized Re, Pt, W, or Mo. In some embodiments, the low work function surface 126 comprises WSe2, MoS2, MoTe2, or h-BN and the high work function surface 128 comprises oxidized or nonoxidized Re, Pt, W, or Mo. In some embodiments, the layer of the high work function surface 128 and/or the low work function surface 126 may include a continuous covering of atoms or nanoparticles across a surface. Alternatively, and/or additionally, the layer of the high work function surface 128 and/or the low work function surface 126 may include atoms or nanoparticles dispersed across the surface with portions of the surface exposed.

Alternatively, and/or additionally, the high work function surface 128 and the low work function surface 126 may comprise suitable conducting material or a combination thereof, such as a metal alloy, a compound, and/or a mixture. For example, the high work function surface 128 may comprise indium tin oxide. Furthermore, the high work function surface 128 and the low work function surface 126 may constitute different materials and may have different structures. For example, the high work function surface 128 may be a semiconductor and the low work function surface 126 may be a metal. In another example, the high work function surface 128 may be a 2D material and the low work function surface 126 may be a heterostructural material. In another non-limiting implementation, the high work function surface 128 and the low work function surface 126 may comprise single and multiwalled carbon nanotubes, graphene flakes, graphitic flakes, diamond clusters, graphitic particles, carbon fibers, carbon ring structures, phosphorus-doped diamond, cesiated diamond, carbon nitride, hydrogenated diamond, nitrogen containing hydrogenated diamond, and boron carbon nitride

The high work function surface 128 and the low work function surface 126 may comprise a treatment applied to the electrode. The surface treatment may include surface features such as roughness, spikes, spheres, pins, pits, pillars, and/or the like. The surface features may be spaced from each other to adjust the work function. The surface treatments may comprise a thin film comprising polycrystalline grains. In at least one implementation, the polycrystalline grains may have a thickness with a quadratic mean ranging between 0.5 to 5 nm. The surface features may be created through deposition techniques, such as PVD, CVD, spin-on coating, self-assembly, etching, lithography, and/or a similar manufacturing process. The surface features may control the sensitivity of tunneling of charge carriers between the electrodes.

The surface treatment of the high work function surface 128 and/or the low work function surface 126 may include a chemical application. The chemical may lower the work function until the desired work function differential is achieved. For example, the low work function surface 126 may be treated with Cs2O to lower its work function. The chemical may comprise Cs2O, CsF, CH3OH, CsCO3, chlorine compounds, fluorine compounds, cesium compounds, non-stoichiometric cesium oxides, and/or cesium fluorides. The electrode surface treatment may aim to increase the work function, and include chemicals such as NO2-PyT (PyT standing for pyrene-tetraone), Br-PyT, Cl-ITO, and/or the like. The chemical may include a uniform layer of atoms or compounds along the length of the high work function surface 128 and/or the low work function surface 126. In some embodiments, the high work function surface 128 and/or the low work function surface 126 may be doped with an impurity, such as Cs2O, CsF, CH3OH, CsCO3, chlorine compounds, fluorine compounds, cesium compounds, non-stoichiometric cesium oxides, and/or cesium fluorides. The dopant may react with the metal of the electrode to vary the electrical properties (e.g., capacitance, the inductance, the resistance, and the conductivity) of the conductive metal. The dopants may vary in carrier concentration and mobility between the high work function surface 128 and the low work function surface 126. For example, the dopant may have a greater carrier concentration at the high work function surface 128 in comparison to the low work function surface 126. The chemical treatment may be evenly spread across the surface of the high work function surface 128 or the low work function surface 126 but only covers a fraction of the total surface area. Alternatively, and/or additionally, the chemical treatment may be applied in an alternating pattern along surface of the high work function surface 128 or the low work function surface 126. The thickness of the application of the chemical treatment varies between 0.1 nanometers to 100 nanometers.

The high work function surface 128 and/or the low work function surface 126 is between 1 nm and 1 μm in thickness. In some embodiments, the high work function surface 128 may have a thickness greater than the low work function surface 126. In some embodiments, the low work function surface 126 may have a thickness greater than the high work function surface 128. For example, the high work function surface 128 may be hundreds of nanometers thick while the low work function surface 126 may be a single angstrom thick. The work function across the high work function surface 128 may differ based on a varying thickness, composition, and treatment applied. Additionally, and/or alternatively, the work function across the low work function surface 126 may differ based on a varying thickness, composition, and treatment applied. The high work function surface 128 and/or the low work function surface 126 may be fabricated using deposition techniques, such as PVD, CVD, spin-on coating, self-assembly, etching, lithography, and/or a similar manufacturing process. Multiple high work function surfaces may be electrically connected to each other in any number of series or parallel configurations. Multiple low work function surfaces may be electrically connected to each other in any number of series or parallel configurations.

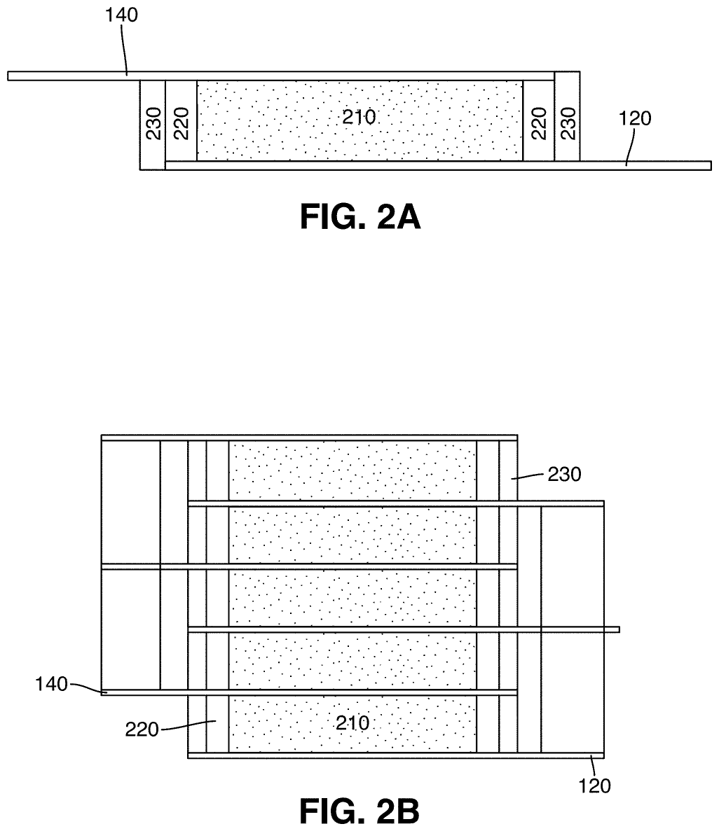

FIG. 2A shows another energy-generating layer comprising a transport medium including a nanoparticle solution, in accordance with some example embodiments. The nanoparticle solution 210 has dielectric properties. The nanoparticle solution 210 may comprise a dielectric liquid including, for example, silicone oil, purified water, hexane, tetradecane, toluene, hydrocarbons, and the like. The nanoparticle solution 210 may include an electrolytic solution. The nanoparticle solution 210 may include a fluid with suspended nanoparticles. The transport medium 130 may comprise a nanoparticle solution 210 interposed between the emitter electrode 120 and the collector electrode 140. The nanoparticle solution 210 may have a thickness of 0.1 nm to 10 μm. The dielectric properties of the nanoparticle solution 210 may enable quantum tunneling of charge carriers between the emitter electrode 120 and the collector electrode 140.

In some embodiments, the nanoparticle solution 210 is encapsulated between the emitter electrode 120 and the collector electrode 140. For example, the nanoparticle solution 210 is sealed between an emitter electrode 120 made of platinum and a collector electrode 140 made of aluminum. The emitter electrode 120 and the collector electrode 140 may require standoffs 220 at the ends of the emitter electrode 120 and the collector electrode 140. Additionally, the standoffs 220 may be dispersed throughout the transport medium 130 to maintain structural support. A sealant 230 may be placed adjacent to the standoffs to retain the nanoparticle solution 210. For example, the sealant 230 may be disposed at the sides of the transport medium 130 to retain the nanoparticle solution 210. Additionally, the standoffs 220 may function as a sealant or including a seal layer. The transport medium 130 comprising the fluid may include one or more solid structures, such as a pillar, placed between the surfaces of the emitter electrode 120 and the collector electrode 140.

FIG. 2B shows a schematic representation of an architecture of an energy conversion device including the nanoparticle solution, in accordance with some example embodiments. As shown, the power-generating cells may encapsulate the nanoparticle solution 210. Multiple liquid chambers may be stacked between the emitter electrodes and the collector electrodes. The standoffs 220 and the sealant 230 may extend continuously between the cells. For example, the sealant 230 may extend continuously in a vertical direction to retain the nanoparticle solution 210. In some embodiments, the standoffs 220 and the sealant 230 may extend continuously between the cells and are only interrupted by the emitter electrode 120 and the collector electrode. The standoffs 220 and the sealant 230 may extend between the emitter and collector electrodes of each cell 150 of the multi-stacked cells. A supporting wall may extend between the multiple liquid chambers to support the stacked architecture. For example, the supporting wall may extend continuously in a vertical direction between the cells to support the stacked multiple cells. The supporting wall may be straight for ensuring the cells extend in a uniform direction. The sealant 230 may be placed adjacent to the wall to retain the liquid within the chambers. The emitter lead 165 and the collector lead 160 may face the outside surface of the sealant 230. Alternatively, and/or additionally, the emitter lead 165 and the collector lead 160 may face the outside surface of the sealant 230.

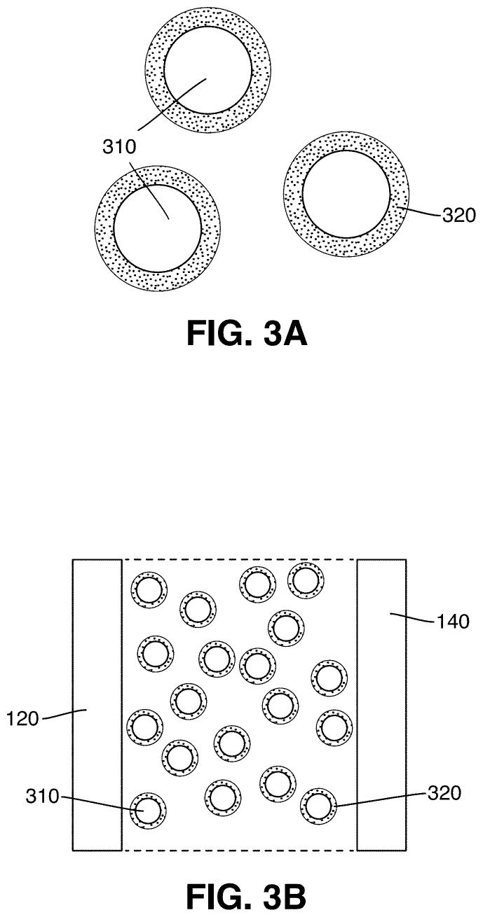

FIG. 3A shows nanoparticles in accordance with some example embodiments. The nanoparticle solution 210 may include nanoparticles 310. The nanoparticles 310 may comprise conductive materials, such as gold, silver, copper, aluminum, titanium, nickel, platinum, lanthanum hexaboride, and/or the like. For example, gold nanoparticles may be immersed in nanoparticle solution 210 comprising tetradecane. In a non-limiting implementation, the nanoparticles may comprise Au, Ag, Pt, Ti, Pt, La, GaN, GaP, InP, InAs, ZnO, ZnS, CdS, CdSe, CdTe, SiO2, Al₂O₃, HfO₂, TiO₂, Mn₃O₄, single and multiwalled carbon nanotubes, graphene flakes, graphitic flakes, diamond clusters, graphitic particles, carbon fibers, and carbon ring structures. The nanoparticles 310 may be more conductive than the nanoparticle solution 210. Some nanoparticles may have materials dissimilar from other nanoparticles. The nanoparticles 310 may have a work function less than the work function of the emitter electrode 120 and greater than the work function of a collector electrode 140. Additionally, the nanoparticles 310 may have a work function less than the work function of the nanoparticle solution 210. The nanoparticles 310 may comprise a conductive material such that the nanoparticles 310 have a work function lower than the collector electrode 140. Some nanoparticles may have a higher work function relative to other nanoparticles. The nanoparticles 310 may be core-shell nanoparticles for enhancing the charge carrier transport between the emitter electrode 120 and the collector electrode 140. The core-shell nanoparticles may include a film 320 having insulative properties. The film 320 may comprise an electrosprayed dipole that encompasses the nanoparticles 310. The film 320 may be a monolayer film having a thickness of fewer than ten nanometers. Additionally, and/or alternatively, the film 320 may include various layers having a thickness of less than 10 nm. The film 320 may have a thickness of less than 10 nm. In some embodiments, the film 320 has a thickness of 0.5 nm. In some embodiments, the film 320 has a thickness of either 0.25 nm or 0.75 nm. The nanoparticles may enable trap-assisted tunneling.

Some nanoparticles may have a larger particle size than other nanoparticles. For example, a nanoparticle may have a diameter of 2 nm and another nanoparticle may have a diameter of 10 nm in the nanoparticle solution 210. In another embodiment, the nanoparticles have a diameter of 3-4 nm. In some embodiments, the nanoparticles have a diameter of 4-5 nm with film 320. The nanoparticles 310 may range in size from 1 to 100 nanometers in diameter. In some embodiments, a self-assembled monolayer may cover the nanoparticles 310. The thin film may comprise an electrosprayed dipole. In some embodiments, nanoparticles having a larger diameter relative to other nanoparticles in the nanoparticle solution 210 may be positioned closer to the low work function surface 126. Alternatively, and/or additionally, nanoparticles having a smaller diameter relative to other nanoparticles in the nanoparticle solution 210 may be positioned closer to the low work function surface 126. In some embodiments, the layer of nanoparticles may include a continuous covering of atoms or nanoparticles across a surface. Alternatively, and/or additionally, the layer of nanoparticles may include atoms or nanoparticles dispersed across the surface with portions of the surface exposed.

In some embodiments, the nanoparticles 310 may be integrated into a solid material rather than a solution. For example, gold nanoparticles may be integrated into alumina or a polymer. The thickness of the solid may range from 0.1 nm to 10 μm. The nanoparticles 310 may be distributed evenly throughout the solid material. The nanoparticles 310 may be distributed closer to one work surface than the other. For example, the nanoparticles 310 may be distributed closer to the low work function surface 126 than the high work function surface 128. In another example, the nanoparticles 310 may be distributed closer to the high work function surface 128 than the low work function surface 126. In some embodiments, nanoparticles having a larger diameter relative to other nanoparticles in the same solid material may be positioned closer to the low work function surface 126. Alternatively, and/or additionally, nanoparticles having a smaller diameter relative to other nanoparticles in the same solid material may be positioned closer to the low work function surface 126. In some embodiments, the transport medium 130 may be treated with a dip coating process or a Langmuir Blodgett coating process to produce core-shell nanoparticles.

FIG. 3B shows nanoparticles in a transport medium interposed between the emitter and the collector in accordance with some example embodiments. The transport medium 130 may also comprise a vacuum, a gas or vapor, or a fluid, formed by, for example, chemical etching.

The nanoparticles 310 may have a work function lower than the work function of the high work function surface 128. The nanoparticles 310 may have a work function lower than the work function of the high work function surface 128 and higher than the work function of the low work function surface 126. In some embodiments, the nanoparticles 310 may have a work function lower than work function of the collector electrode 140. In some embodiments, the nanoparticles 310 may have a work function lower than the work function of the collector electrode 140 and higher than the work function of the emitter electrode 120.

In some implementations, the nanoparticles 310 may have a work function higher than the work function of the low work function surface 126. The nanoparticles 310 may have a work function higher than the low work function surface 126 and lower than the work function of the high work function surface 128. In some embodiments, the nanoparticles 310 may have a work function higher than the work function of the emitter electrode 120. In some embodiments, the nanoparticles 310 may have a work function higher than the work function of the emitter electrode 120 and lower than the work function of the collector electrode 140.

In some embodiment, the nanoparticles and/or the traps may reach equilibrium between the emitter electrode 120 and the collector electrode 140 after power has been generated over a period of time. The traps may be the nanoparticles or defects included in the transport medium 130. If the current drops, then the emitter electrodes and the collector electrodes may be disconnected, and then reconnected. Optionally, the emitter electrodes and the collector electrodes may be grounded between the disconnecting and reconnecting the electrodes. This enables the energy conversion capacity of the energy conversion device 105 to be rapidly recovered. After reconnecting the electrodes by the electrical switch, the currents described earlier will be reestablished and these charge carriers will charge the nanoparticles and/or the traps across the transport medium 130.

A switch may be configured to intermittently connect the emitter electrode 120 and the collector electrode 140. The switch may be configured to disconnect, ground, and rapidly reconnect the emitter electrode 120 and the collector electrode 140. The switch may be configured to activate based on a current from the emitter electrode 120 to the collector electrode 140 satisfying a threshold.

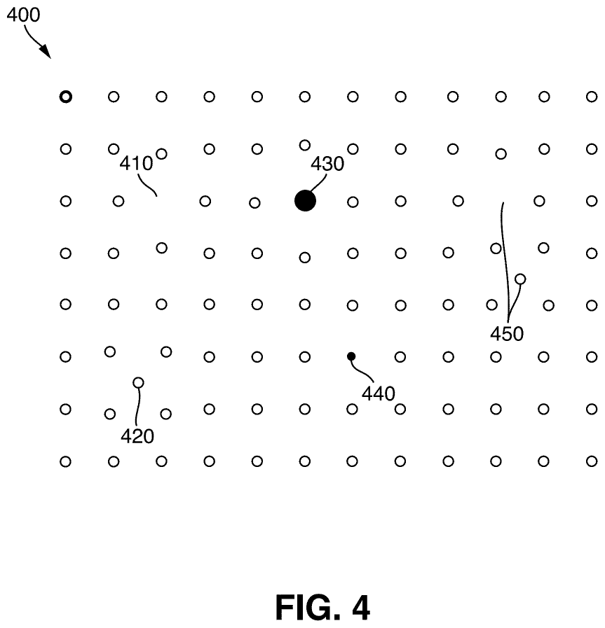

FIG. 4 shows an atomic lattice including a trap for trap-assisted charge carrier transport, in accordance with some example embodiments. The atomic layer 400 may represent the transport medium 130 over which a charge carrier must pass between the emitter electrode 120 and the collector electrode 140. The atomic layer 400 may comprise a crystalline structure having a monoatomic solid layout. The crystalline structure features adjoining atoms evenly distributed across a planar area in their natural state. In its natural state, the atomic layer 400 has a balance of bonds between the atoms. Traps may be introduced that disrupt the spacing of the atoms in the atomic layer 400. Traps may be embodied by a defect in the atomic layer or as a nanoparticle in the atomic layer. The traps may include a natural defect in the atomic layer 400 or a metal contaminant introduced into the atomic layer 400. For example, the introduction of a Boron atom may disrupt the spacing in the crystalline structure. The traps may be electron sites that promote electron or other charge carrier transportation across the atomic layer 400. Optionally, the atomic layer 400 need not have a crystalline structure. The traps may be formed in other structures, such as a gas or liquid, enabling the atomic bonding to freely associate with adjacent atomic structures. The atomic layer 400 may comprise an atomic lattice.

A trap may include an imbalance of bonding between adjacent atoms. This imbalance attracts or repels charge carriers facilitating transport across the transport medium. Examples of traps include a vacancy trap 410, an interstitial trap 420, a substitutional larger atom 430, and a substitutional smaller atom 440. The vacancy trap 410 may be characterized by an imbalanced bond missing an electron. For example, an imbalanced bond due to a vacancy of an oxygen atom attracts electrons. The vacancy trap 410 is missing an electron that provides a conductive site as the electron crosses the transport medium 130. The interstitial trap 420 may be characterized by an imbalanced bond with an extra bond. For example, an imbalanced bond due to an extra oxygen atom repels electrons. A substitutional larger atom 430 having a greater atomic mass than the adjacent atoms may also disrupt the continuity of the balanced bonds in the atomic layer 400. For example, a substitutional larger atom 430, such as In, may be placed in the atomic layer 400, resulting in stronger bonds between the In atom and the immediately surrounding atoms. These stronger bonds promote electron mobility by repelling electrons to available electron sites. The substitutional smaller atom 440 having a smaller atomic mass than the adjacent atoms may also disrupt the continuity of the balanced bonds in the atomic layer 400. For example, the substitutional smaller atom 440, such as B, may be placed in the atomic layer 400, resulting in weaker bonds between the B atom and the immediately surrounding atoms. These stronger bonds promote electron mobility by repelling electrons to available electron sites. Electron mobility may be guided across the transport medium 130 with proximate vacancies and interstitial pairs. A proximate vacancy and interstitial pair may be considered a Frenkel Pair 450.

The nanoparticles may encourage quantum tunneling across the transport medium 130. The term “quantum tunneling” is not limited to the definition of a charge carrier passing from one end of the transport medium 130 to the opposite end of the transport medium 130. The term “quantum tunneling” may also include direct tunneling, trap-assisted tunneling, phonon-assisted tunneling, Fowler-Nordheim tunneling, and leakage tunneling. For example, quantum tunneling may occur between charge carrier traps in the transport medium 130 without traversing the entire transport medium 130 in a single movement. Charge carrier traps in solid transport medium may enable trap-assisted tunneling or Poole-Frenkel emission. The transport medium 130, including a solid material, may include traps. The traps may be created by defects or nanoparticles. The traps enhance electron transport across the transport medium 130. For example, the traps may be missing oxygen atoms that provide locations for the electrons to cross the transport medium 130. The missing oxygen atoms may act as extra sites that attract electrons. The nanoparticle solution 210 may use quantum tunneling to transport charge carriers across the transport medium 130.

The atomic layer 400 may be a gas, vapor, solid, solution, a solution with nanoparticles, or a solid with nanoparticles. The atomic layer 400 may have insulating or semiconductor properties, including low electrical conductivity and/or low thermal conductivity. The atomic layer 400 may comprise any material for the transport medium 130. The trap may comprise the nanoparticles embedded in a solid material or nanoparticles situated in a fluid. The traps may have strong or excessive electron bonds in comparison to the electron bonds in the atomic layer 400. The traps may have weak or vacant electron bonds in comparison to the electron bonds in the atomic layer 400. The traps may comprise a discrete site of a bonding imperfection in the atomic layer 400. The traps enhance electron transport across the transport medium 130. In some embodiments, traps may be formed at defects within the insulator or semiconductor crystalline structure of the atomic layer 400.

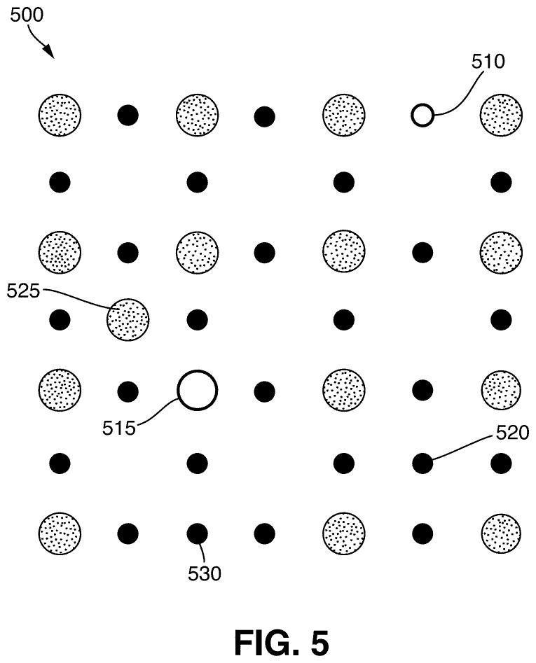

FIG. 5 shows a polyatomic layer including a trap for trap-assisted charge carrier transport, in accordance with some example embodiments. The polyatomic layer 500 may represent the transport medium 130 over which a charge carrier may pass between the emitter electrode 120 and the collector electrode 140. The polyatomic layer 500 may comprise a crystalline structure having a polyatomic solid layout analogous to the Ta2O5 system. In one non-limiting implementation, the polyatomic layer 500 may comprise an amorphous film. In some embodiments, the polyatomic layer 500 has insulative properties. The crystalline structure of the polyatomic layer 500 may feature adjoining atoms evenly distributed across a planar area in its natural state. In its natural state, the polyatomic layer 500 has a balance of bonds between the atoms. Traps may be introduced that disrupt the spacing of the atoms in the polyatomic layer 500. Traps may be embodied by a defect in the polyatomic layer or as a nanoparticle in the polyatomic layer. The traps may be a natural defect in the polyatomic layer or a metal contaminate introduced into the polyatomic layer 500. For example, a trap may be a hydrogen atom in place of an oxygen atom in an Al2O3 atomic structure. The traps increase charge carrier mobility by promoting charge carrier transport across the polyatomic layer 500. The polyatomic layer 500 may comprise a polyatomic lattice.

A trap may include an imbalance of bonding between adjacent atoms in the polyatomic layer 500. This imbalance attracts or repels charge carriers facilitating transport across the transport medium. Examples include a small vacancy trap 510, a large vacancy trap 515, a small interstitial trap 520, a large interstitial trap, a large substitutional trap, and a small substitutional trap 530. The small vacancy trap 510 may be characterized by an imbalanced bond missing an electron due to the absence of an atom having a relatively small atomic mass. For example, an imbalanced bond attracts electrons between two tantalum atoms due to a vacancy of an oxygen atom in a Ta2O5 system. The large vacancy trap 515 may be characterized by an imbalanced bond missing an electron due to the absence of an atom having a relatively large atomic mass. For example, an imbalanced bond attracts electrons between two oxygen atoms due to a vacancy of the larger tantalum atom in a Ta2O5 system. The small interstitial trap 520 may be characterized by an imbalanced bond with an extra electron bond due to the presence of an extra atom having a relatively small atomic mass. For example, an imbalanced bond repels electrons between tantalum atoms due to an extra smaller oxygen atom in a Ta2O5 system, the oxygen atom having a smaller atomic mass than the tantalum. The large interstitial trap 525 may be characterized by an imbalanced bond with an extra electron bond due to the presence of an extra atom having a relatively large atomic mass. For example, an imbalanced bond repels electrons between oxygen atoms due to an extra larger tantalum atom in a Ta2O5 system. The large interstitial trap includes a substitutional larger atom having a greater atomic mass than the adjacent atoms may also disrupt the continuity of the balanced bonds in the polyatomic layer 500. For example, a substitutional larger atom, such as a tantalum atom, may be placed in the polyatomic layer 500, resulting in stronger bonds between immediately surrounding oxygen atoms. These stronger bonds promote electron mobility by repelling electrons to available electron sites. The small substitutional trap 530 includes a substitutional smaller atom having a smaller atomic mass than the adjacent atoms may also disrupt the continuity of the balanced bonds in the polyatomic layer 500. For example, the substitutional smaller atom, such as an oxygen atom, may be placed in the polyatomic layer 500, resulting in weaker bonds between the immediately surrounding oxygen atoms. These weaker bonds promote electron mobility by repelling electrons across the transport medium 130. Charge carrier mobility (e.g., electron mobility) may be guided across the transport medium 130 with proximate vacancies and interstitial pairs. A proximate vacancy and interstitial pair may be considered a Frenkel Pair.

The polyatomic layer 500 may be a gas, vapor, solid, solution, a solution with nanoparticles, or a solid with nanoparticles. The polyatomic layer 500 may have insulating or semiconductor properties, including low electrical conductivity and/or low thermal conductivity. The polyatomic layer 500 may comprise any material for the transport medium 130. The trap may comprise the nanoparticles embedded in a solid material or nanoparticles situated in a fluid. The traps may have strong or excessive electron bonds in comparison to the electron bonds in the polyatomic layer 500. The traps may have weak or vacant electron bonds in comparison to the electron bonds in the polyatomic layer 500. The traps may include a discrete site of a bonding imperfection in the polyatomic layer 500. The traps may enhance charge carrier transport across the transport medium 130. In some embodiments, traps may be formed at defects within the insulating or semiconductor crystalline structure of the polyatomic layer 500.

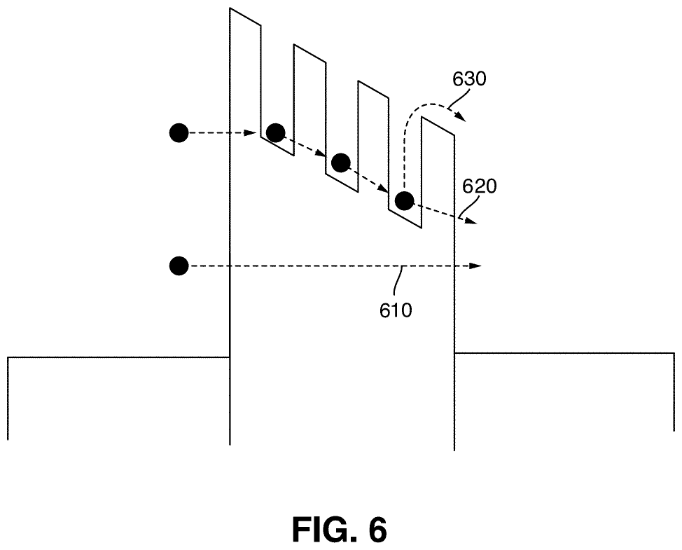

FIG. 6 shows a bandgap diagram depicting applied charge carrier quantum tunneling techniques and Poole-Frenkel Emission in accordance with some example embodiments. The term “quantum tunneling” is not limited to the definition of a charge carrier passing from one end of the transport medium 130 to the opposite end of the transport medium 130. The term “quantum tunneling” may also include direct tunneling, trap-assisted tunneling, phonon-assisted tunneling, Fowler-Nordheim tunneling, and leakage tunneling. For example, quantum tunneling may occur between charge carrier traps in the transport medium 130 without traversing the entire transport medium 130 in a single movement. Quantum tunneling 610 may characterize the charge carrier transportation across the nanoparticle solution-based transport medium and the solid-state transport medium 130. Quantum tunneling 610 may optimize charge carrier migration between the emitter electrode 120 and the collector electrode 140. Quantum tunneling 610 may optimize charge carrier mobility from electrodes having a lower work function to electrodes having a higher work function.

The Quantum tunneling effect may be controlled by the thickness of the transport medium 130. Quantum tunneling is very sensitive to the distance that a charge carrier (e.g., an electron) travels between the emitter electrode 120 and the collector electrode 140. The transport medium 130 may be resized to increase the quantum tunneling effect. A thinner transport medium 130 may be preferable in its capacity to promote higher charge carrier migration according to quantum tunneling effects. A thicker transport medium 130 generally reduces the quantum tunneling effect.

As shown in FIG. 6, a transport medium 130 has a high energy barrier compared to the emitter electrode. Even though the energy barrier is higher than the emitter electrode, a finite probability exists that a charge carrier may cross through the transport medium 130 based on the wavelike behavior of the charge carrier on a quantum scale. If the transport medium 130 is sufficiently thin, the charge carrier may tunnel through the energy barrier of the transport medium 130 from a lower work function to a higher work function. In some non-limiting implementations, the charge carriers may flow through the transport medium 130 from the higher work function to the lower work function. As shown, the emitter electrode 120 has a lower work function than the collector electrode 140 has a higher work function.

The nanoparticle solution-based transport medium and the solid-state transport medium may be sufficiently thin to support quantum tunneling. The emitter electrode 120 and the collector electrode 140 may be configured to have a sufficient work function differential to facilitate electron transportation across the transport medium 130. The nanoparticle solution-based transport medium and the solid-state transport medium may be adjusted to increase the quantum tunneling effect.

As shown in FIG. 6, trap-assisted tunneling 620 may occur between two metal electrodes. Trap-assisted tunneling 620 may be depicted with a bandgap diagram in accordance with some example embodiments. Trap-assisted tunneling 620 may characterize the charge carrier transportation across the transport medium. Trap-assisted tunneling 620 may optimize electron migration between the emitter electrode 120 and the collector electrode 140 by splitting the energy barrier into two or more parts. This enables a consecutive tunnel through thinner energy barriers and increases the probability that a charge carrier will pass through the transport medium 130. Trap-assisted tunneling 620 enables thicker transport mediums in comparison to transport mediums utilizing quantum tunneling 610.

The nanoparticles may control the probability and frequency of charge carriers passing through the transport medium 130 using the trap-assisted tunneling effect. Generally, additional nanoparticles in the transport medium 130 increase the probability that a charge carrier will pass through the transport medium 130 via trap-assisted tunneling 620. The nanoparticles may be resized to increase the probability and frequency of charge carriers passing through the transport medium 130 using the trap-assisted tunneling effect. Alternatively, and/or additionally, traps may be introduced into the atomic layer to split the energy barrier of the transport medium 130 into two or more parts. Generally, more traps in the transport medium 130 increase the probability that a charge carrier will pass through the transport medium 130 via trap-assisted tunneling 620.

As shown in FIG. 6, Poole-Frenkel emission 630 may occur between two metal electrodes. Poole-Frenkel emission 630 may be depicted with a bandgap diagram in accordance with some example embodiments. Poole-Frenkel emission 630 may characterize the charge carrier transportation across the transport medium 130. Poole-Frenkel emission 630 may optimize charge carrier migration between the emitter electrode 120 and the collector electrode 140. The nanoparticles may control the probability and frequency of charge carriers passing through the transport medium 130 using the Poole-Frenkel emission effect. Generally, additional nanoparticles in the transport medium 130 increase the probability that the charge carrier will pass through the transport medium 130 via Poole-Frenkel emission 630. The nanoparticles may be resized to increase the probability and frequency of charge carriers passing through the transport medium 130 using the Poole-Frenkel effect. Alternatively, and/or additionally, traps may be introduced into the atomic layer to split the energy barrier into two or more parts. Generally, more traps in the transport medium 130 increase the probability that a charge carrier will pass through the transport medium 130 via Poole-Frenkel emission 630. In at least one non-limiting implementation, the traps in the transport medium 130 form a discontinuous energy band or defect energy band.

The term “work function” is not limited to the definition of the minimum quantity of energy required to remove a charge carrier from a surface (e.g., an electrode) to a vacuum. The term “work function” may include the ability to manipulate the potential energy landscape for moving a charge carrier from a surface (e.g., an electrode) to another surface. The potential energy landscape may be characterized by the work functions of the surfaces and the various features of the energy barrier, such as an energy barrier height relative to the fermi level, an energy barrier height relative to vacuum, an energy barrier slope, a density of traps within the energy barrier, a depth of the traps within the energy barrier, and an intermediate stage adjacent to the energy barrier. Manipulating the characteristics of the energy barrier enables various non-equilibrium states for moving a charge carrier to another surface.

The energy barrier may be modified by adjusting the energy barrier height relative to the fermi level. This height may be adjusted by combining a first material and a second material that determine a maximum height of the energy barrier relative to the fermi level. For example, the first material may determine the initial barrier height and the second material may raise or lower the energy barrier height, determining the maximum height. In one non-limiting example, the first material and second material are oxides where the second material lowers the energy barrier height relative to the fermi level as initially determined by the first material.

The energy barrier may be modified by adjusting the energy barrier height relative to the vacuum level. This energy barrier height relative to the vacuum level may be adjusted by combining a first material and a second material that determine a height of the energy barrier relative to the vacuum level. For example, the first material may determine the initial barrier height relative to the vacuum level and the second material may raise or lower the energy barrier height relative to the vacuum level. In one non-limiting example, the first and second materials are oxides where the second material lowers the energy barrier height initially determined by the first material.

The energy barrier may be modified by adjusting the energy barrier slope. The energy barrier slope may be adjusted by combining a first material and a second material that comprise the energy barrier. For example, the first material may have a first barrier slope and the second material may have a second barrier slope. Combining the first material and the second material causes the first barrier slope to decrease the energy required to move the charge carrier through the transport medium 130 at a higher rate than the first barrier slope standing alone. In one non-limiting example, the first and second materials are oxides where the second material has a steeper slope relative to the first material. Energy barrier slope may be the biggest determining factor of the non-equilibrium state.

The energy barrier may be modified by adjusting a density of traps within the energy barrier. The density of traps may vary depending on the nanoparticles in the fluid and/or solid. The density of traps may vary depending on the current across the transport medium 130. The density of traps may vary depending on the number of defects or impurities or deposition method of the transport material. In a non-limiting example, gold nanoparticles may be immersed in nanoparticle solution 210 comprising tetradecane. The density of traps within the energy barrier may be adjusted based on the number and the diameter of the nanoparticles.

The energy barrier may be modified by adjusting a depth of traps within the energy barrier. The depth of the traps may vary depending on the conductivity, resistance, and density of nanoparticles in the fluid and/or solid. The depth of the traps may vary depending on whether the nanoparticle is mobile within the nanoparticle fluid. The depth of the traps may depend on the atomic nature of the defect or impurity or the nature of atomic bonding with surrounding atoms in the transport material. In a non-limiting example, gold nanoparticles may be immersed in nanoparticle solution 210 comprising tetradecane. The depth of the traps within the energy barrier may be adjusted based on the density and the diameter of the nanoparticles.

The energy barrier may be modified by an intermediate stage adjacent to the energy barrier. The intermediate stage adjacent to the energy barrier may be adjusted by combining a first material and a second material that comprise the energy barrier. For example, the first material may determine a fermi level and the second material may determine the height and width of intermediate stage. In one non-limiting example, the first and second materials are oxides where the second material creates the intermediate stage. Various intermediate states may exist between a fermi level and the energy required to move the charge carrier to vacuum. There may be other defect states at the intermediate stage, which enable a subset of charge carriers to escape to the emitter or the collector at a different energy level. In one non-limiting example, the defect states may be included in a graduated density to vary the slope of the energy barrier.

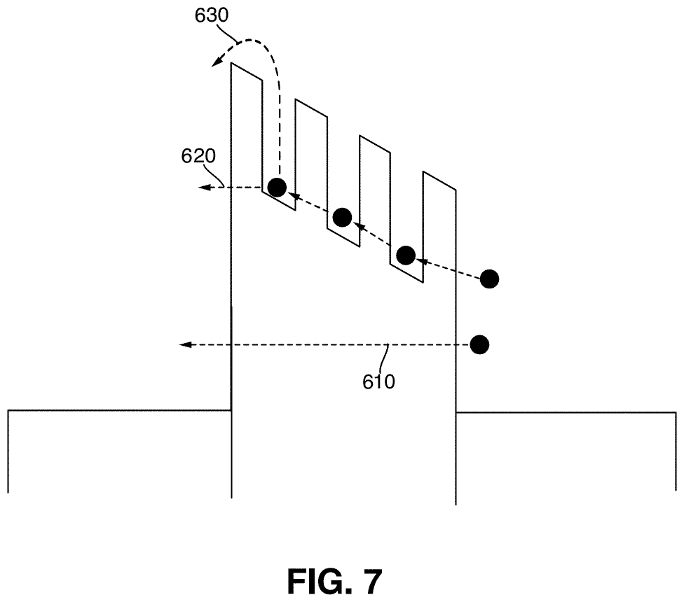

FIG. 7 shows another bandgap diagram depicting applied charge carrier tunneling techniques and Poole-Frenkel Emission in accordance with some example embodiments. In some embodiments, quantum tunneling 610 may optimize charge carrier mobility from surfaces having a higher work function to surfaces having a lower work function. The transport medium 130 may be resized to increase the quantum tunneling effect. A thinner transport medium 130 may be preferable in its capacity to promote higher electron migration according to quantum tunneling effects. A thicker transport medium 130 generally reduces the quantum tunneling effect. The nanoparticle solution-based transport medium and the solid-state transport medium may be sufficiently thin to support quantum tunneling. The emitter electrode 120 and the collector electrode 140 may be configured to have a sufficient work function differential to facilitate charge carrier transportation across the transport medium 130. The nanoparticle solution-based transport medium and the solid-state transport medium may be adjusted to increase the quantum tunneling effect. Various combinations of materials and/or operational conditions may determine whether the charge carriers travel from the high work function surface 128 to the low work function surface 126.

In a similar manner, trap-assisted tunneling 620 may optimize charge carrier mobility from surfaces having a higher work function to surfaces having a lower work function. Trap-assisted tunneling 620 may optimize electron migration by splitting the energy barrier of the transport medium 130 into two or more parts. Splitting the energy barrier enables a consecutive tunnel through thinner energy barriers and increases the probability that charge carriers will pass through the transport medium 130. In some embodiments, the charge carrier may travel to a higher work function energy barrier to a lower work function energy barrier. Trap-assisted tunneling 620 enables thicker transport mediums in comparison to transport mediums utilizing quantum tunneling 610.

The nanoparticles may control the probability and frequency of charge carriers passing through the transport medium 130 using the trap-assisted tunneling effect. Generally, additional nanoparticles in the transport medium 130 increase the probability that a charge carrier will pass through the transport medium 130 via trap-assisted tunneling 620. The nanoparticles may be resized to increase the probability and frequency of charge carriers passing through the transport medium 130 using the trap-assisted tunneling effect. Alternatively, and/or additionally, traps may be introduced into the atomic layer to split the energy barrier of the transport medium 130 into two or more parts. Generally, more traps in the transport medium 130 increase the probability that a charge carrier will pass through the transport medium 130 via trap-assisted tunneling 620. Various combinations of materials and/or operational conditions may determine whether the charge carriers travel from the high work function surface 128 to the low work function surface 126.

In a similar manner, Poole-Frenkel emission 630 may optimize charge carrier mobility from surfaces having a higher work function to surfaces having a lower work function. The nanoparticles may control the probability and frequency of charge carriers passing through the transport medium 130 using the Poole-Frenkel emission effect. Generally, additional nanoparticles in the transport medium 130 increase the probability that a charge carrier will pass through the transport medium 130 via Poole-Frenkel emission 630. The nanoparticles may be resized to increase the probability and frequency of charge carriers passing through the transport medium 130 using the Poole-Frenkel effect. Alternatively, and/or additionally, traps may be introduced into the atomic layer to split the energy barrier into two or more parts. Generally, more traps in the transport medium 130 increase the probability that a charge carrier will pass through the transport medium 130 via Poole-Frenkel emission 630. Various combinations of materials and/or operational conditions may determine whether the charge carriers travel from the high work function surface 128 to the low work function surface 126.

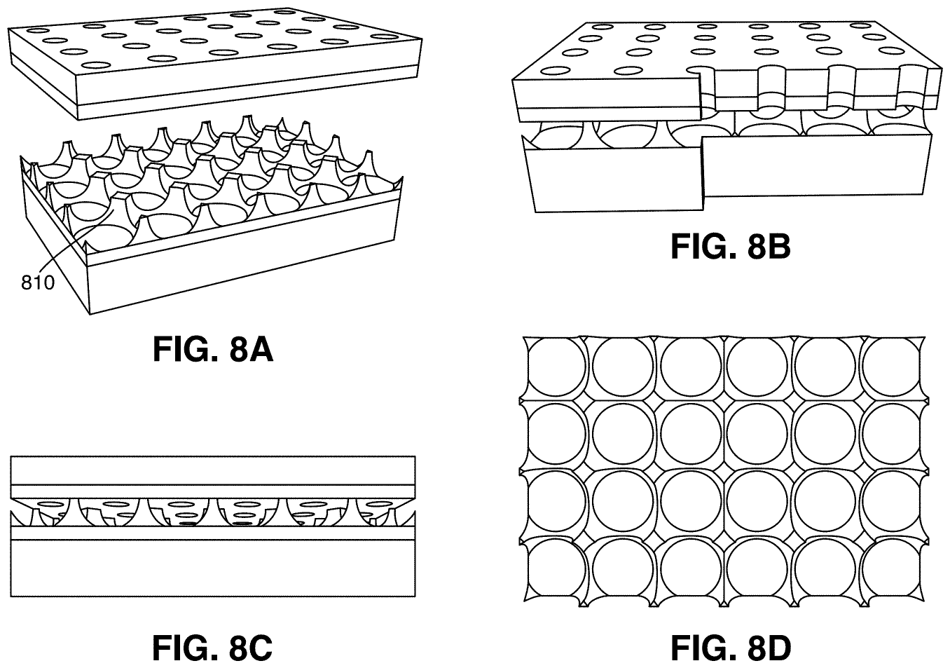

FIGS. 8A-8D show various views of standoff pillars resulting from an etch, in accordance with some example embodiments. The transport medium 130 may be incapable of supporting the emitter electrode 120 and/or the collector electrode 140. For example, the transport medium 130 may be unstable if the transport medium 130 primarily comprises a nanoparticle solution 210 or other non-solid material. The transport medium 130 comprising the nanoparticle solution 210 may integrate the standoff pillars 810 for stability of the individual cell and the stacked architecture.

The standoff pillars 810 may be interposed between the emitter electrode 120 and the collector electrode 140 in the transport medium 130. The standoff pillars 810 may have low thermal and electrical conductivity. The standoff pillars 810 may have a larger footprint near the emitter electrode 120 than the collector electrode 140. Alternatively, the standoff pillars 810 may have a larger footprint near the collector electrode 140 for modifying the work function. The standoff pillars 810 may connect at or near the emitter electrode 120. The top and bottom of the standoff pillars 810 may be substantially planar at both the points of contact with the emitter electrode 120 and the collector electrode 140.

The standoff pillars 810 may be created using an etch process. A gas or vapor may etch material in the transport medium 130. The gas or vapor may have high selectively against etching the emitter electrode 120, the collector electrode 140, or the substrate. In other embodiments, the standoff pillars 810 may be created using deposition techniques, such as PVD, CVD, spin-on coating, self-assembly, etching, lithography, and/or a similar manufacturing process.

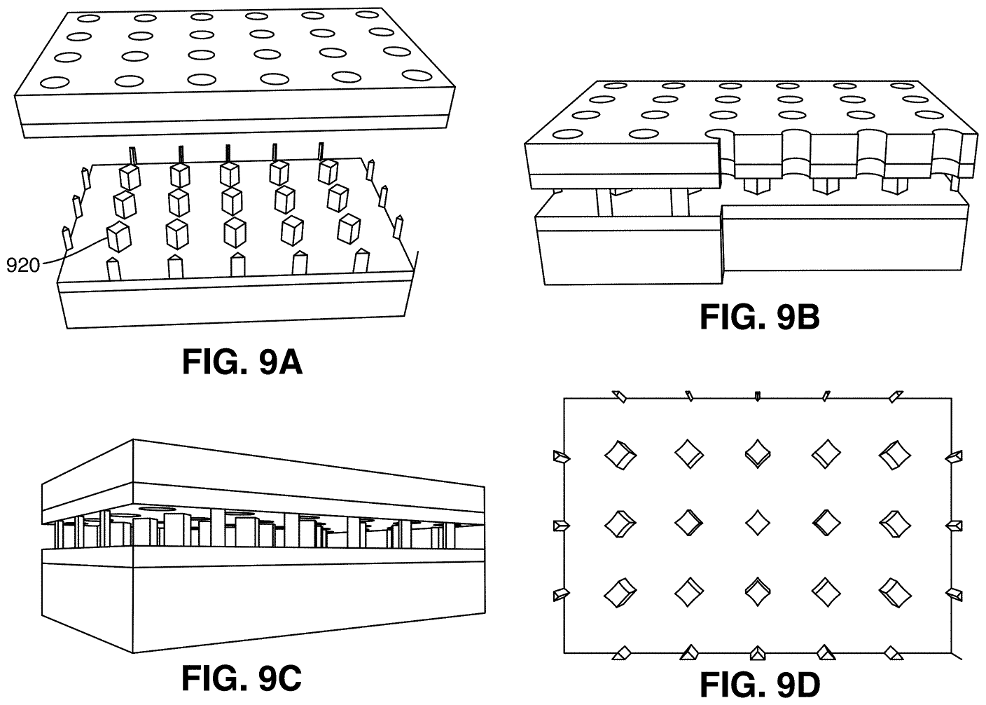

FIGS. 9A-9D show an exploded view of standoff columns resulting from an etch, in accordance with some example embodiments. The transport medium 130 may be incapable of supporting the emitter electrode 120 and/or the collector electrode 140. For example, the transport medium 130 may be unstable if the transport medium 130 primarily comprises a nanoparticle solution 210. The transport medium 130 comprising the nanoparticle solution 210 may integrate standoff columns for stability of the individual cell and the stacked architecture.

The standoff columns 920 may be interposed between the emitter electrode 120 and the collector electrode 140 in the transport medium 130. The standoff columns 920 may have low thermal and electrical conductivity. The standoff columns 920 may have a larger footprint near the emitter electrode 120 than the collector electrode 140. Alternatively, the standoff columns 920 may have a larger footprint near the collector electrode 140 for modifying the work function. The standoff columns 920 may connect at or near the emitter electrode 120. The top and bottom of the standoff columns 920 may be substantially planar at both the points of contact with the emitter electrode 120 and the collector electrode 140.

The standoff columns 920 may be created using an etch process. A gas or vapor may etch material in the transport medium 130. The gas or vapor may have high selectively against etching the emitter electrode 120, the collector electrode 140, or the substrate. In other embodiments, the standoff columns 920 may be created using deposition techniques, such as PVD, CVD, spin-on coating, self-assembly, etching, lithography, and/or a similar manufacturing process.

Non-solid transport mediums may require standoff pillars to maintain spacing between the emitter electrode 120 and the collector electrode 140. The standoff pillars 810 and standoff columns 920 may be scaled to maximize electron flow. For example, the standoff pillars 810 and standoff columns 920 are designed to provide maximum support with the smallest available footprint. The standoff pillars 810 and standoff columns 920 may be thermally insulated and electrically insulated to maximize electron flow. The standoff pillars 810 and standoff columns 920 may be free-standing nanolaminate structures.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The implementations set forth in the foregoing description do not represent all implementations consistent with the subject matter described herein. Instead, they are merely some examples consistent with aspects related to the described subject matter. Although a few variations have been described in detail herein, other modifications or additions are possible. In particular, further features and/or variations can be provided in addition to those set forth herein. For example, the implementations described above can be directed to various combinations and sub-combinations of the disclosed features and/or combinations and sub-combinations of one or more features further to those disclosed herein. In addition, the logic flows depicted in the accompanying figures and/or described herein do not necessarily require the particular order shown, or sequential order, to achieve desirable results. The scope of the following claims may include other implementations or embodiments. An electron is considered to be a charge carrier. The term “electron” may be interchangeable with charge carrier.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

While the foregoing is directed to implementations of the present disclosure, other and further implementations of the disclosure may be devised without departing from the basic scope thereof, and the scope thereof is determined by the claims that follow.

What is claimed is:

1. An apparatus, comprising:
a transport medium comprising a nanoparticle suspended in a dielectric, the transport medium having a first side and a second side, the first side opposing the second side, the nanoparticle comprising a conductive metal, the conductive metal at least partially covered by a monolayer film, the monolayer film being less conductive than the conductive metal;
a first surface disposed at the first side of the transport medium, the first surface having a first work function; and
a second surface disposed at the second side of the transport medium, the second surface having a second work function,
wherein the first work function is lower than the second work function.

2. The apparatus of claim 1, wherein a nanoparticle work function is lower than the second work function.

3. The apparatus of claim 1, wherein the dielectric is a solution comprising at least one of silicone oil, purified water, hexane, toluene, and tetradecane.

4. The apparatus of claim 1, wherein the monolayer film has a thickness less than ten nanometers, and wherein the conductive metal of the nanoparticle comprises at least one of gold, silver, platinum, titanium, platinum, lanthanum hexaboride, and copper.

5. The apparatus of claim 1, wherein the nanoparticle further comprises a core-shell nanoparticle, the core-shell nanoparticle including a conductive core and an insulative film.

6. The apparatus of claim 1, wherein the first surface comprises a surface feature including at least one of a spike, a sphere, a pin, and a pillar.

7. The apparatus of claim 1, wherein the first surface comprises at least one of Cs2O, CsF, CH3OH, CsCO3, chlorine compounds, fluorine compounds, cesium compounds, non-stoichiometric cesium oxides, and cesium fluorides.

8. The apparatus of claim 1, wherein the first surface comprises a semi-conductive material, the semi-conductive material being doped with at least one of aluminum, antimony, bismuth, gold, phosphorous and boron.

9. The apparatus of claim 1, wherein the first surface has covalent bonding in-plane and Van der Waals bonding out of plane, and wherein the first surface comprises at least one of WSe2, MoS2, MoTe2, and h-BN.

10. The apparatus of claim 1, wherein a first end and a second end of the transport medium include a sealant and a standoff, and wherein the first surface has a surface thickness less than one nanometer, the first surface including at least one of graphene, Si2BN, and borophene.

11. An apparatus, comprising:
a first electrode having a first surface, the first surface having a first work function;
a second electrode having a second surface, the second surface having a second work function; and
a transport medium interposed between the first surface and the second surface, the transport medium comprising traps suspended in a dielectric,
wherein the first work function is lower than the second work function.

12. The apparatus of claim 11, wherein the dielectric comprises a lattice of Ta2O5 and a tantalum dopant and the traps include an opening in the lattice of Ta2O5 where no atom is bonded to the tantalum dopant.

13. The apparatus of claim 11, wherein the first electrode and the second electrode have a surface treatment comprising at least one of Cs2O, CsF, CH3OH, CsCO3, chlorine compounds, fluorine compounds, cesium compounds, non-stoichiometric cesium oxides, and cesium fluorides.

14. The apparatus of claim 11, wherein the dielectric is a polycrystalline layer having a crystalline structure, the traps are nanoparticles including a conductive metal, and wherein the first electrode comprises a semi-conductive material and the second electrode comprises at least one of Ti, Ni, Cu, Pd, Ag, Hf, ITO, W, Ir, Pt, and Au.

15. An apparatus, comprising:
a first electrode having a first surface and a second surface, the first surface and the second surface being associated with a first work function;
a second electrode facing the first surface, the second electrode associated with a second work function;
a third electrode facing the second surface, the third electrode associated with the second work function;
a first transport medium interposed between the first electrode and the second electrode; and
a second transport medium interposed between the first electrode and the third electrode,
wherein the second electrode and the third electrode are electrically coupled and the first work function is lower than the second work function.

16. The apparatus of claim 15, wherein the first electrode and the second electrode are on opposing sides of the first transport medium, and wherein the second electrode and the third electrode are on opposing sides of the second transport medium.

17. The apparatus of claim 15, wherein the first surface contacts the first transport medium and the second surface contacts the second transport medium.

18. The apparatus of claim 15, further comprising:
a first lead, the first lead oriented in a first direction non-parallel to the first surface and the second surface, the first lead electrically connected to the second electrode and the third electrode; and
a second lead, the second lead oriented in a second direction non-perpendicular to the first lead, the second lead electrically coupled to the first electrode.

19. The apparatus of claim 18, wherein the first direction is the same as the second direction, and wherein the first lead extends at least a distance between the second electrode and the third electrode.

20. The apparatus of claim 18, wherein the second lead faces an exposed region of the first electrode, and wherein the first lead is on an opposing side of the exposed region of the first electrode.
